(19) United States
(12) Patent Application Publication
(10) Pub. No.: US 2003/0003402 A1
(43) Pub. Date: Jan. 2, 2003

(54) Method and apparatus to prevent pattern collapse of photoresist layer due to capillary forces

(75) Inventor: Marina Plat, San Jose, CA (US)

Correspondence Address: David A. Blumental, FOLEY & LARDNER, Washington Harbour, 3000 K Street, N.W., Suite 500, Washington, DC, 20007-5109, US

(73) Assignee: ADVANCED MICRO DEVICES, INC.

(21) Appl. No.: 09/895,394

(22) Filed: Jul. 2, 2001

(51) Int. Cl. G03F 7/00; B05C 11/00

(52) U.S. Cl. 430/313; 430/311; 430/323; 118/58

(57) ABSTRACT

There is provided a method for forming a photoresist layer for photolithographic applications that reduces or eliminates pattern collapse due to capillary forces on photoresist structures during spin developing and/or spin rinsing. The photoresist layer is developed in a near vertical orientation with developer solution showered onto the photoresist layer. Rinse solution is showered onto the photoresist layer and the photoresist layer is dried by flowing air or nitrogen over the surface. Also provided are a semiconductor fabrication method and a semiconductor processing apparatus configured to accomplish the disclosed methods.

### BACKGROUND OF THE INVENTION

This invention is related generally to a method of making a semiconductor device and specifically to photolithographic methods for forming submicron features involving processing of the photoresist layer to prevent pattern collapse during developing and rinsing due to capillary forces.

The semiconductor industry has progressively reduced the size of components and connectors on integrated circuits in the pursuit of increased computational power and device speed. State of the art semiconductor devices are approaching the limit of feature sizes that may be formed using conventional photolithography fabrication methods. One of the limits being approached involves the minimum dimension of photoresist structures that can be used during fabrication.

Photolithography employs photoresist to create a patterned structure that protects the underlying surface from subsequent fabrication steps, such as chemical etching. There are two types of photoresists in common use, positive photoresists and negative photoresists. Positive photoresists are sensitized when exposed to ultraviolet light so that exposed areas will dissolve in a developer solution leaving behind unexposed areas. Negative photoresists are hardened by exposure to ultraviolet light so exposed areas are inhibited from being dissolved by the developer solution while unexposed areas are dissolved.

Using the example of a positive photoresist process, a conventional photolithography method for producing narrow line is illustrated in FIGS. 1A and 1B. Supported by a substrate 1 is provided a material layer that forms a surface 2 in which it is desired to form a first and second narrow line. A positive photoresist layer 3 is formed over the surface 2. A first region 5 and a second region 7 in the photoresist layer 3 are simultaneously exposed to electromagnetic radiation 8, such as ultraviolet or actinic light, through openings 11 and 13 in a mask or reticle 9, as illustrated in FIG. 1A. The mask 9 comprises a pattern of lines and spaces of opaque material 10, which prevent transmission of light 8, and transparent openings 11, 13. The terms mask and reticle are used interchangeably in the semiconductor arts, with the term reticle often referring to a mask used in step and repeat exposure systems. The photoresist layer 3 is then developed wherein the exposed regions 5 and 7 are removed (when employing a negative photoresist, the unexposed areas are removed), while the unexposed region 6 remains, as illustrated in FIG. 1B. A gas or liquid etching medium is then permitted to reach the underlying surface 2 through the openings 15, 17 in the photoresist layer 3 to etch narrow lines 16, 18 in surface 2, which are separated by an some distance 19, as illustrated in FIG. 1C.

In the developing step, the exposed areas of a positive photoresist are removed by a developer solution to leave the desired pattern image on the surface. In many cases, the developing step is accomplished by spin coating a developer solution onto the photoresist layer. Spin coating is a process that involves rapidly revolving a wafer while depositing a solution on the wafer near the axis of revolution so the solution is distributed over the wafer by centrifugal force. At the end of the developing step, the surface must be rinsed to stop the developing reaction and remove the developer solution from the surface. In many cases, the rinsing step is accomplished by spraying a rinse solution onto the rapidly spinning surface. Typical positive photoresist developer solutions are alkaline solutions diluted with water, which require only a water rinse. Negative photoresist developer can be either an alkaline solution or organic solvents, which require rinsing with water or organic solvents (e.g. n-butlyl acetate) respectively. After rinsing, the substrate is dried in preparation for further processing.

As the width of narrow lines is reduced, the width of the photoresist structures used to create the narrow lines must be reduced. A practical limit being approached in semiconductor feature sizes results from the photoresist structures becoming so thin in the width direction, e.g. the narrow line distance 19 in FIG. 1C, with respect to the photoresist layer thickness that they lack the structural rigidity to withstand the forces induced by capillary forces of liquid between them when the surface is spin developed, spin rinsed and dried. As shown in FIG. 2A, as feature sizes are reduced, the spacing between opaque regions 30 on the mask 24 are reduced, which results in exposed regions 25, 27, that are illuminated by light 28, and unexposed regions 26 both having narrow widths. When developed, the photoresist features 26 are thin to provide a narrow line 34, and are closely spaced to make the photoresist openings 35, 37 narrow, as illustrated in FIGS. 2A and 2B. As illustrated in FIG. 2C, as the photoresist pattern layer is spin coated, a capillary meniscus 31, 32, 33 of developer or rinse solution forms between the narrow spaces 37 adjacent photoresist structures 26, 38, 39, which pulls the structures together due to surface tension and the capillary forces induced during spin coating of the developer solution or the rinse solution, or during drying following spin coating of the rinse solution. Thin structures of relatively weak photoresist material can collapse under such capillary forces, as illustrated by photoresist structures 38 and 39, which renders the pattern on the surface unusable. Thus, the prior art methods of photolithography cannot form structures below a critical aspect ratio dimension which is limited by the mechanical strength of the photoresist when spin coating of developer and rinse solutions is employed.

### BRIEF SUMMARY OF THE INVENTION

According to one aspect of the present invention, there is provided a method of forming a photoresist layer, comprising the steps of providing a surface depositing a photoresist layer on the surface, exposing the photoresist layer through a mask to create an exposed area of photoresist and an unexposed area of photoresist positioning the surface so the surface and the photoresist layer are approximately vertical, developing the photoresist layer by showering a developer solution on the photoresist layer, rinsing the photoresist layer by showering a rinse solution on the photoresist layer, and drying the photoresist layer by flowing a gas over the photoresist layer.

According to another aspect of the present invention, there is provided a method of making a semiconductor device, comprising the steps of forming at least one semiconductor device on a substrate forming an insulating layer over the semiconductor device forming a photoresist layer over the insulating layer, exposing the photoresist layer through a mask to create an area of exposed photoresist and an area of unexposed photoresist, positioning the substrate so the substrate and the photoresist layer are approximately vertical, developing the photoresist layer by showering a developer solution on the photoresist layer to form a line/space patterns in the photoresist layer, rinsing the photoresist layer by showering a rinse solution on the photoresist layer, drying the photoresist layer by flowing air or NO₂ gas over the photoresist layer, forming a narrow line space resist pattern on top of the insulating layer using dry etch, for example, followed by forming a conductive layer in the narrow line space.

According to another aspect of the present invention, there is provided a semiconductor device made by using the methods described herein.

According to another aspect of the present invention, there is provided an apparatus for processing semiconductor wafers, comprising a fixture configured to hold a semiconductor wafer comprising a surface, a means for rotating the fixture configured so the semiconductor wafer can be positioned so that the surface is approximately vertical, a first nozzle configured to shower a liquid on the surface of the semiconductor wafer while the fixture positions the semiconductor wafer so that the surface is approximately vertical, and a duct configured to flow a gas over the surface of the semiconductor while the fixture positions the semiconductor wafer so that the surface is approximately vertical. In an alternative to this embodiment the apparatus further comprises a first reservoir fluidically coupled to the first nozzle, and a second nozzle fluidically coupled to a second reservoir and configured to shower a liquid on the surface of the semiconductor wafer while the fixture positions the semiconductor wafer so that the surface is approximately vertical.

### BRIEF DESCRIPTION OF THE DRAWINGS

FIGS. 1A, 1B and 1C are side cross sectional views of a conventional method of making line space patterns for semiconductor devices

FIGS. 2A, 2B and 2C are a side cross sectional view of a conventional method of making semiconductor lines where the narrow lines are closely spaced.

FIG. 3 is a process block diagrams of a method of making a photoresist layer.

FIG. 4 is a side cross sectional view of a method of developing, rinsing and drying a photoresist layer.

FIGS. 5A, 5B and 5C are side cross sectional views of a preferred embodiment method of making closely spaced narrow lines employing a positive photoresist.

FIG. 6 is a partial side cross sectional view of a completed semiconductor device made by the method of the preferred embodiments of the present invention.

FIG. 7 is a diagram of an apparatus for accomplishing the methods of the present invention.

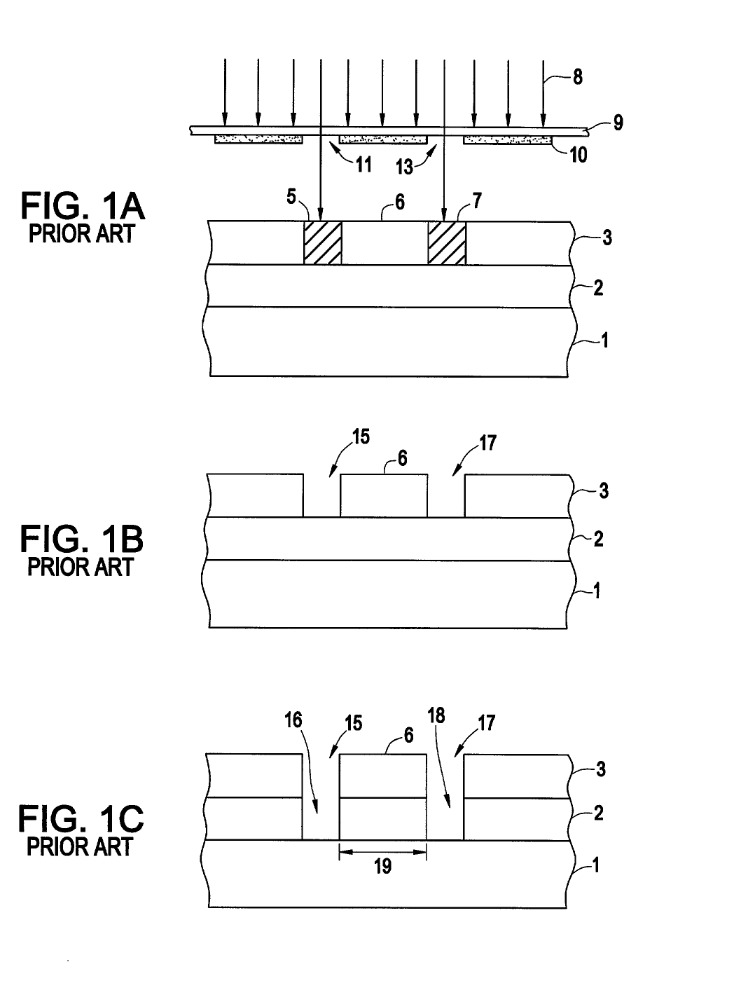

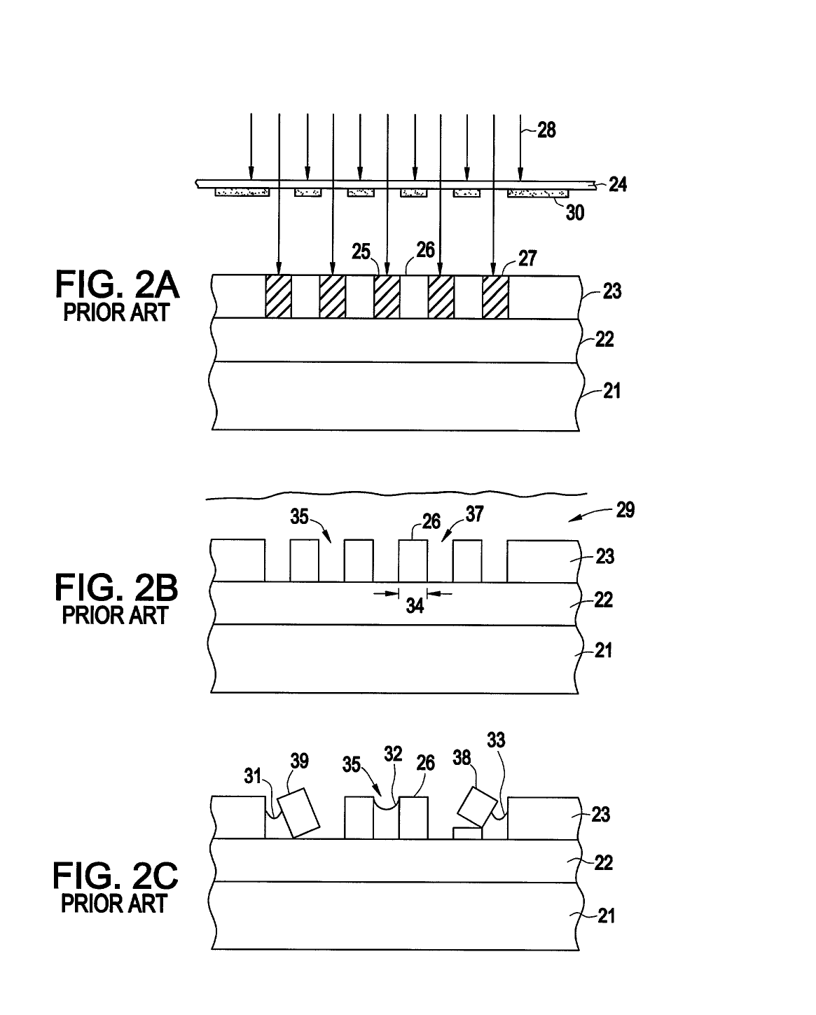

### DETAILED DESCRIPTION OF THE PREFERRED EMBODIMENTS

The present inventor has realized that the line density may be increased and the inter-line spacing may be reduced if photoresist patterns are not subjected to capillary forces when developed, rinsed and dried. By turning the surface containing a photoresist more or less vertical and showering developer and/or rinse solution onto the surface, the capillary forces induced in photoresist structures by spin coating can be reduced.

The present invention solves the problem of photoresist structure collapse during spin coating of developer and rinse solutions by changing the way these steps are accomplished and providing an apparatus for shower developing and shower rinsing. The developer solution and the rinse solution are applied to the photoresist while the layer is held in a near vertical position followed by an air, NO₂ or nitrogen drying step so that the photoresist structures are not subjected to the capillary forces that occur when the surface is spin coated with developer and/or rinse solution. By solving the problem of photoresist pattern collapse due to capillary forces, pattern dimensions can be reduced to dimensions smaller than achievable in the current state of the art.

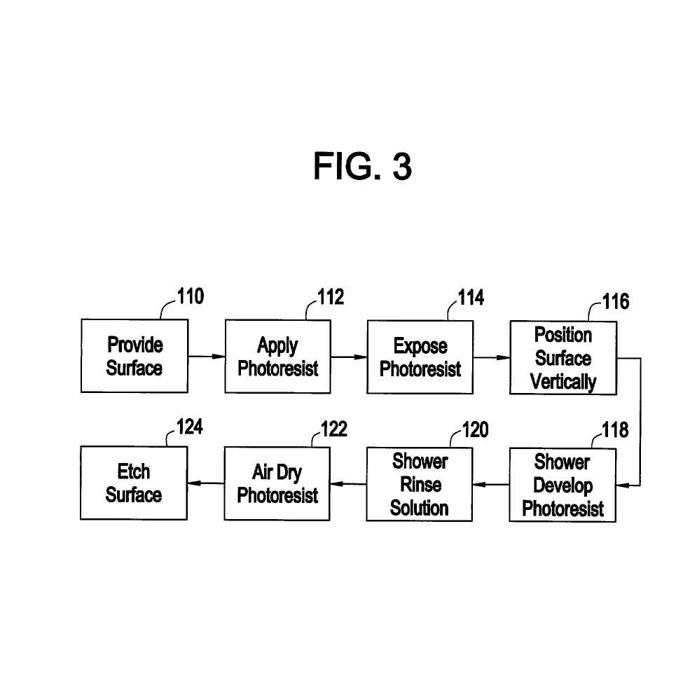

A preferred embodiment of the present invention method is diagrammed in FIG. 3. Among the sequence of steps required to fabricate a finished semiconductor or integrated circuit are the steps of:

providing (step 110) a surface to be photolithographically processed, which may involve preparing the surface with a dehydration bake and priming the surface with a pre-resist coating;

applying (step 112) a layer of positive photoresist to the surface, which may involve depositing the photoresist on the surface, such as by spin coating or vapor coating to form a uniform, adherent and defect free polymer film of the desired thickness, and performing a soft-bake to drive off the solvent component;

exposing (step 114) the photoresist to actinic or suitable ultraviolet light shown through a mask so only selected areas (the pattern) are illuminated;

positioning (step 116) the surface in a near vertical position;

developing (step 118) the photoresist by showering it with developer solution, such as an alkaline aqueous solution, to remove exposed areas of photoresist;

rinsing (step 120) the photoresist layer by showering it with an aqueous solution (e.g. water) to remove the developer solution from the surface;

drying (step 122) the photoresist layer by flowing air, N0₂ or nitrogen over the surface; and

continuing on with subsequent semiconductor fabrication steps (step 124), such as etching the surface to form a narrow line in the open areas, adding layers of insulator or conductor material, and removing the photoresist.

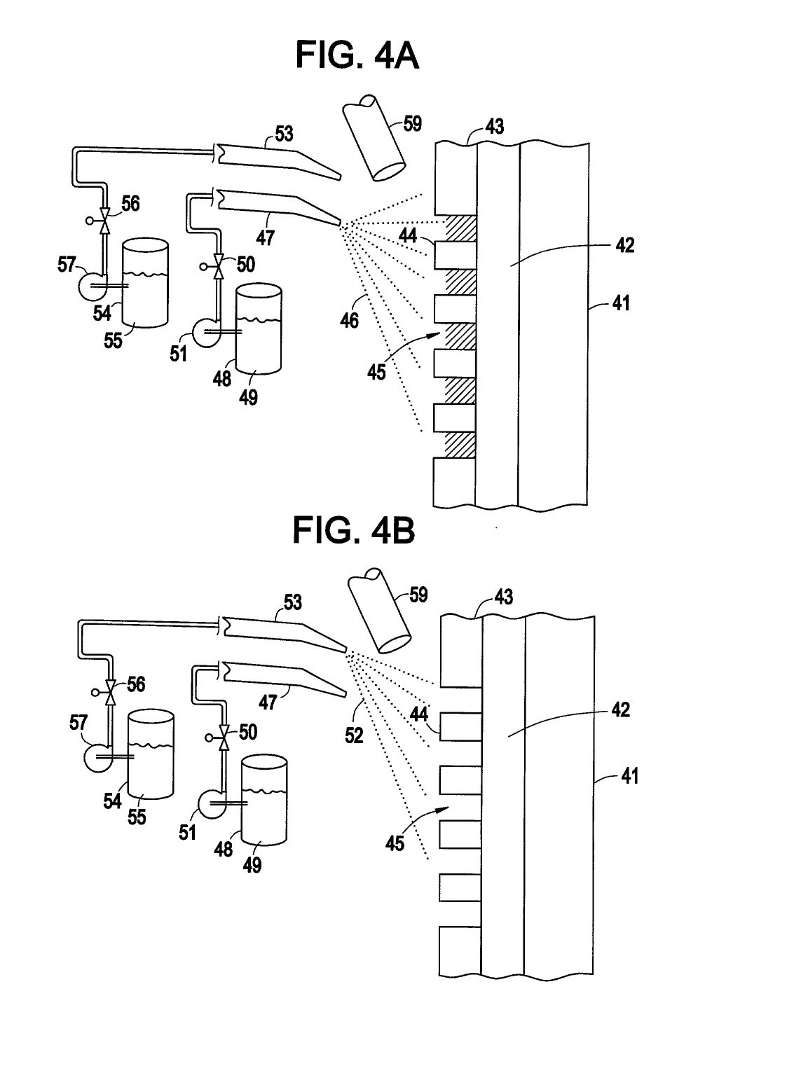

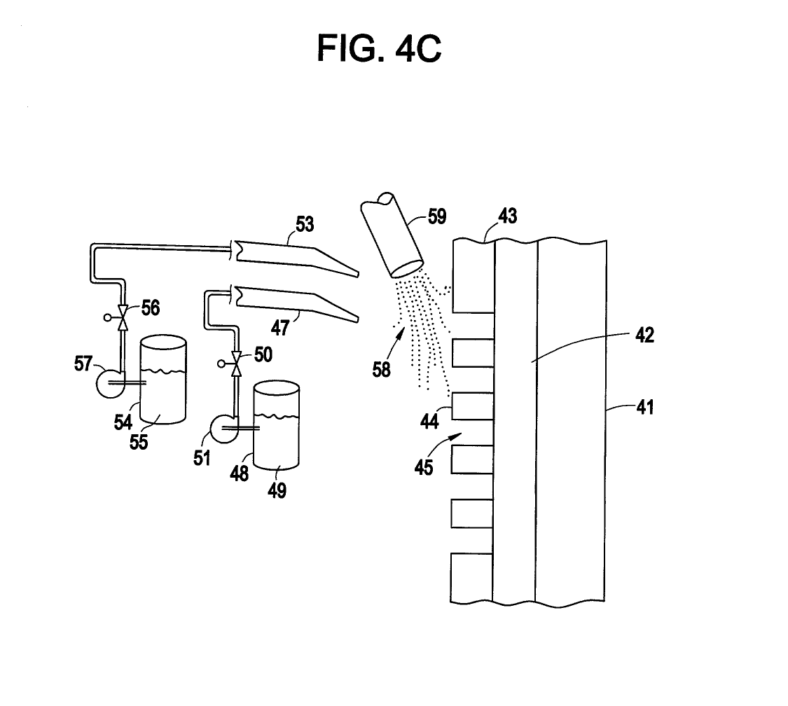

A preferred embodiment for shower developing and/or rinsing a positive photoresist followed by air, NO₂ or nitrogen drying is illustrated in FIGS. 4A, 4B and 4C. A photoresist layer 43, which has been deposited upon a surface 42 layered on a substrate 41, has been exposed to create exposed areas 45 and unexposed areas 44. As illustrated in FIG. 4A, the surface 42 is oriented in a near vertical position and developer solution 46 is showered from a first nozzle 47, which is the developer nozzle, so that droplets of developer solution 46 fall onto the photoresist layer 43. The first nozzle 47 is coupled to a reservoir 48 which holds the developer solution 49, with a valve 50 and a pump 51 provided in some embodiments to control the flow of developer solution through the first nozzle 47.

As illustrated in FIG. 4B, while the surface 42 remains in a near vertical position a rinse solution 52 is showered from a second nozzle 53, which is the rinse nozzle, so that droplets of rinse solution 52 fall onto the photoresist layer 43. The second nozzle 53 is coupled to a reservoir 54 which holds the rinse solution 55, with a second valve 56 and a second pump 57 provided in some embodiments to control the flow of rinse solution through the second nozzle x53.

As illustrated in FIG. 4C, while the surface 42 remains in a near vertical position, a gas 58, such as dry air, NO₂ or nitrogen, is flowed over the surface from a duct 59 to dry the photoresist layer. The duct is coupled to a source of the gas, such as a compressed nitrogen bottle (not shown), with a gas valve (not shown) provided for controlling the flow of the gas over the photoresist layer.

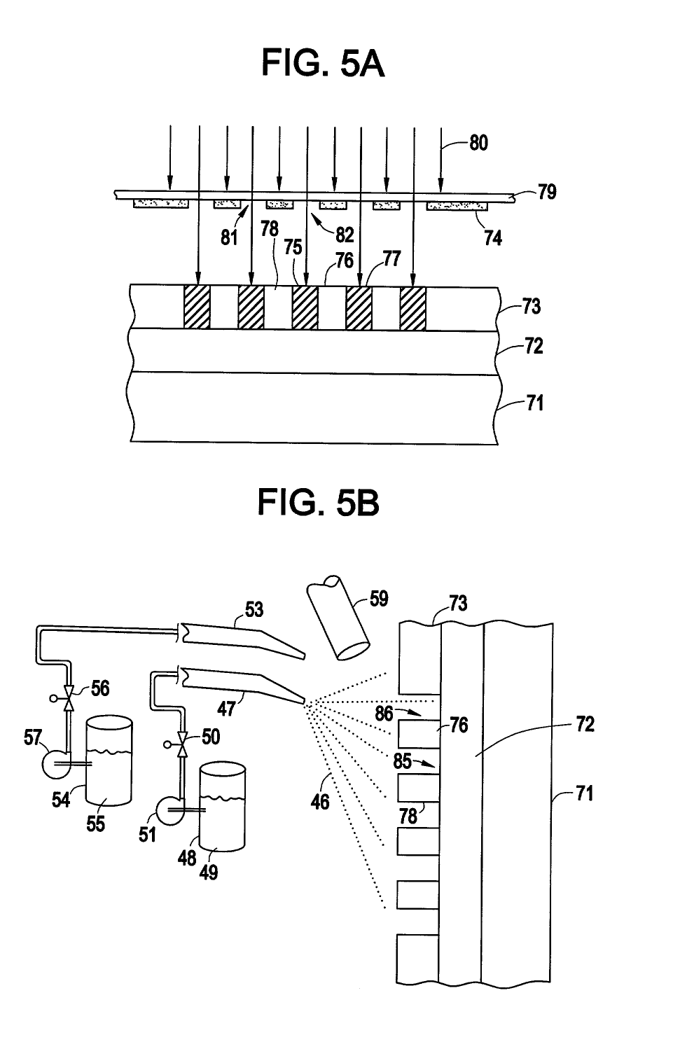

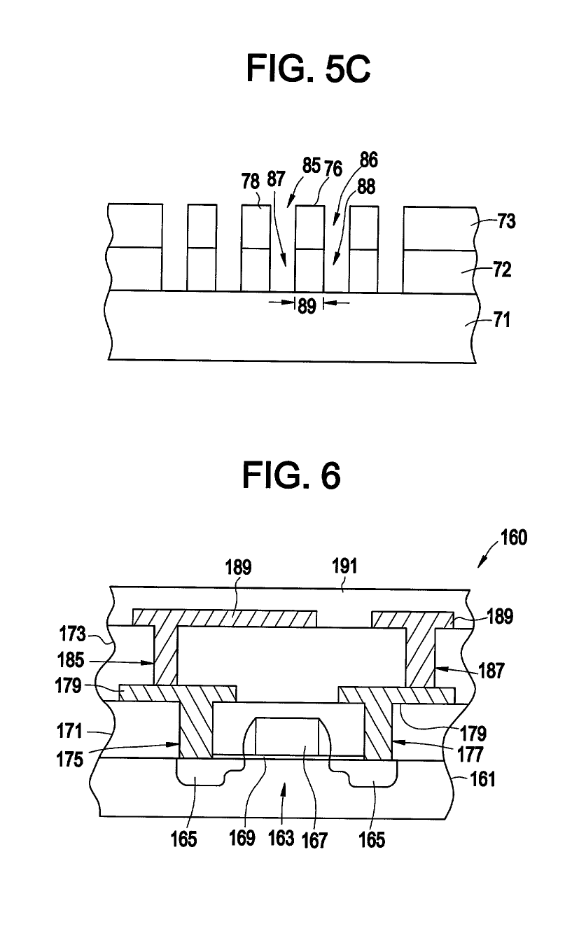

FIGS. 5A, 5B and 5C illustrate a method of forming narrow lines using a positive photoresist according to a preferred embodiment of the present invention. A positive photoresist layer 73 is deposited on a layer that forms a surface 72 layered on a substrate 71. The photoresist layer 73 is then exposed to radiation 80, such as actinic light or other suitable UV radiation, through openings 81, 82 in the opaque pattern 74 in a mask or reticle 79 to form exposed regions 75, 77 in the photoresist layer 73, as illustrated in FIG. 5A. In this step, the exposed regions 75, 77 of the positive photoresist layer 73 are rendered soluble to developer solution. Other regions 76, 78 of the photoresist layer 73 are shielded by the opaque layer 74 of the mask 79 and are not exposed. The exposed photoresist regions 75, 77 are separated by a non-exposed region 76, which remains insoluble to the developer.

As illustrated in FIG. 5B, after the exposing step, the photoresist layer 73 oriented into a near vertical position and is developed by showering developer solution 46 from nozzle 47 onto the photoresist layer 73 to remove the exposed photoresist regions 75, 77 from the unexposed regions 76, 78, thereby providing first and second openings 85, 86 to layer 73. Photoresist regions 76 and 78 are not removed during development and are used in subsequent steps to resist processes such as etching or implanting of the underlying surface 72. Similarly, after developing is complete, rinse solution is showered onto the photoresist layer 73 from rinse nozzle 53 while the surface is held in a near vertical position. Once the photoresist material has been so rinsed, the surface is dried by flowing a gas, such as air, NO₂ or nitrogen, over the photoresist layer 73 from duct 59. Developer nozzle 47 is supplied with developer solution 49 from reservoir 48, impelled by pump 51 and regulated by valve 50. Similarly, rinse nozzle 53 is supplied with rinse solution 55 from reservoir 54, impelled by pump 57 and regulated by valve 56.

As illustrated in FIG. 5C, with openings 85, 86 provided in the photoresist layer 73, narrow lines 87, 88 are formed in surface 72 by providing an etching gas or an etching liquid to the surface 72 through the openings 85, 86 in the photoresist layer 73, as illustrated in FIG. 5C. Thus, narrow lines 87 and 88 separated by narrow spaces, region 89, are formed in surface 72.

While FIGS. 5A-5C illustrate only a few narrow lines for ease of explanation, it should be understood that a semiconductor device contains a vast plurality of line and spaces.

The surface 72, 92, shown in the embodiment of FIGS. 5A-5C, containing the narrow lines may comprise any layer of material used in an electronic or semiconductor device, such as an insulating, metal or semiconductor layer. Preferably, surface 72, 92 comprises an insulating layer in a semiconductor device, such as a first level insulating layer or an intermetal dielectric.

FIG. 6 illustrates a completed semiconductor device 160 containing the narrow lines made by the methods of a preferred embodiment. The semiconductor device 160 contains a substrate 161, which may be a semiconductor (such as silicon or gallium arsenide, etc.), a glass or a plastic material. One or more active elements 163 are formed on the substrate 161. The active element may comprise at least one of a MOSFET, a MESFET, a bipolar transistor, a capacitor, a resistor or any other desired device. For example, FIG. 6 illustrates a MOSFET 163.

The MOSFET 163 contains doped source and drain regions 165 in the substrate 161, a gate electrode 167 with sidewall spacers and a gate dielectric 169 between the gate electrode and the channel region in the substrate 161. At least one insulating layer overlies the active element 163. For example, the at least one insulating layer includes a first level insulating layer 171 and a first intermetal dielectric 173, as illustrated in FIG. 6. It should be understood that there may be other plural intermetal dielectric layers above layer 173 that contain narrow lines. The insulating layers 171, 173 may comprise any dielectric layer, such as at least one of silicon oxide, silicon nitride, silicon oxynitride, fluorinated silicon oxide, aluminum oxide, tantalum oxide, BPSG, PSG, BSG or spin on glass. It should be noted that the insulating layers 171, 173 may comprise plural sublayers of different dielectric materials, if desired. The MOSFET 163, also includes conductive electrodes 179 made of a conductive material.

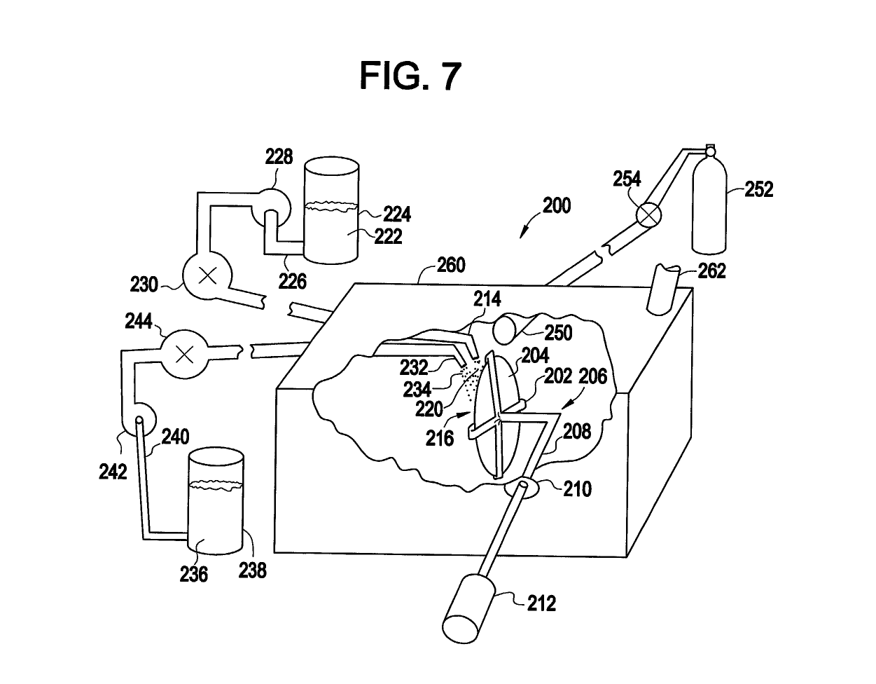

Another preferred embodiment of the present invention comprising an apparatus 200 for accomplishing the methods disclosed herein is illustrated in FIG. 7. A fixture 202 is configured to securely holding a semiconductor wafer 204 so the surface 216 of the semiconductor wafer 204 can be addressed. The fixture 202 is mechanically coupled to a pivot mechanism 206 which may be any mechanical assembly capable of rotating the fixture through at least approximately ninety (90) degrees (i.e. rotating from near horizontally to near vertically oriented), including a shaft 208 through a bearing 210, a hinge (not shown), or a bendable material (e.g. plastic or rubber—not shown). The pivot mechanism 206 and/or the fixture 202 may be coupled to a mechanical device for rotating the fixture, such as a drive motor 212, or configured to be manually rotated, such as by a hand crank (not shown) or lever (not shown). A first nozzle 214 is positioned near the fixture 202 so that when the semiconductor wafer 204 is held in the fixture 202 in a near vertical orientation a fine spray 220 of liquid will contact the surface 216. In a preferred embodiment, the first nozzle expels a fine spray 220 of developer solution 222 from a developer solution reservoir 224 via developer tubing 226, impelled by a developer solution pump 228 with fluid flow regulated by a developer solution valve 230. A second nozzle 232 is positioned near the fixture 202 when oriented in an approximately vertical position so that a fine spray 234 of rinse solution 236 will contact the surface 216. The rinse solution 236 is provided from a reservoir 238 via rinse solution tubing 240, impelled by a rinse solution pump 242 with fluid flow regulated by a rinse solution valve 244. A duct 250 coupled to a gas source, such as a nitrogen bottle 252 and regulated by a gas valve 254, is positioned so that gas from the duct 250 will flow across the semiconductor wafer 204 when the fixture 202 is positioned in a near vertical orientation. The fixture 202, nozzles 214, 232 and duct 250 may be positioned within an enclosure 260 to confine, possibly for recycling, developer solution and/or rinse solution droplets and/or to control humidity during the drying step. Thus a vent 262 is included for venting gas from the enclosure 260.

The terms “near vertical” and “approximately vertical” as used herein means oriented so the plane formed by the surface is within thirty-degrees (plus or minus) of the gravity vector, and preferably within fifteen degrees (plus or minus) of the gravity vector, and includes perfectly parallel to the gravity vector.

While the invention has been described in detail and with reference to specific embodiments thereof, it will be apparent to one skilled in the art that various changes and modifications can be made therein without departing from the scope of the invention. Thus, the breadth and scope of the present invention should not be limited by any of the above-described exemplary embodiments, but should be defined only in accordance with the following claims and their equivalents.

1. A method of forming a photoresist layer, comprising the steps of:
providing a surface;
depositing a photoresist layer on the surface;
exposing the photoresist layer through a mask to create an exposed area of photoresist and an unexposed area of photoresist; and
positioning the surface so the surface and the photoresist layer are approximately vertical, and then performing the steps of:
(a) developing the photoresist layer by applying a developer solution on the photoresist layer;
(b) rinsing the photoresist layer by applying a rinse solution on the photoresist layer; and
(c) drying the photoresist layer by flowing a gas over the photoresist layer.

2. The method of claim 1, wherein the gas comprises air.

3. The method of claim 1, wherein the gas comprises nitrogen dioxide.

4. The method of claim 1, wherein the rinse solution comprises water.

5. A method of making a semiconductor device, comprising the steps of:
forming at least one semiconductor device on a substrate;
forming an insulating layer over the semiconductor device;
forming a photoresist layer over the insulating layer;
exposing the photoresist layer through a mask to create an area of exposed photoresist and an area of unexposed photoresist;
positioning the substrate so the substrate and the photoresist layer are approximately vertical, and then performing the steps of:
(a) developing the photoresist layer by applying a developer solution on the photoresist layer to form an opening in the photoresist layer,
(b) rinsing the photoresist layer by applying a rinse solution on the photoresist layer, and
(c) drying the photoresist layer by flowing a gas over the photoresist layer; and
forming a narrow line in the insulating layer;

6. The method of claim 5, wherein the gas comprises air.

7. The method of claim 5, wherein the gas comprises nitrogen dioxide.

8. The method of claim 5, wherein the rinse solution comprises water.

9. The method of claim 5, wherein the narrow line extends to the at least one semiconductor device or to a second conductive layer above the at least one semiconductor device.

10. A semiconductor device made by the method of claim 5.

11. An apparatus for processing semiconductor wafers, comprising:
a fixture configured to hold a semiconductor wafer having a surface;
a means for rotating the fixture configured so the semiconductor wafer can be positioned so that the surface is approximately vertical;
at least one nozzle configured to shower at least one liquid on the surface of the semiconductor wafer while the fixture positions the semiconductor wafer so that the surface is approximately vertical; and
a duct configured to flow a gas over the surface of the semiconductor while the fixture positions the semiconductor wafer so that the surface is approximately vertical.

12. The apparatus according to claim 11, wherein the at least one nozzle comprises a first nozzle fluidically coupled to a first reservoir, and a second nozzle fluidically coupled to a second reservoir.

13. The apparatus according to claim 12, wherein the at least one fluid comprises a developer solution and a rinse solution, and wherein the first reservoir is configured to supply the developer solution to the first nozzle and wherein the second reservoir is configured to supply the rinse solution to the second nozzle.

14. The apparatus according to claim 11, wherein the duct is fluidically coupled to a gas source.

15. The apparatus according to claim 14, wherein the gas source comprises a source of air.

16. The apparatus according to claim 14, wherein the gas source comprises a source of nitrogen.

17. The apparatus according to claim 12, further comprising:
a first pump fluidically coupled between the first reservoir and the first nozzle; and
a first valve fluidically coupled to the first pump.

18. The apparatus according to claim 17, further comprising:
a second pump fluidically coupled between the second reservoir and the second nozzle; and
a second valve fluidically coupled to the second pump.

19. The apparatus according to claim 18, further comprising an enclosure surrounding the fixture, the first nozzle, the second nozzle and the duct.

20. A method of forming a photoresist layer, comprising the steps of:
providing a surface;
depositing a photoresist layer on the surface;
exposing the photoresist layer through a mask to create an exposed area of photoresist and an unexposed area of photoresist; and
positioning the surface so the surface and the photoresist layer are approximately vertical during at least one of the following steps:
(a) developing the photoresist layer by applying a developer solution on the photoresist layer;
(b) rinsing the photoresist layer by applying a rinse solution on the photoresist layer; and
(c) drying the photoresist layer by flowing a gas over the photoresist layer.
